(19) United States
(12) Patent Application Publication
(10) Pub. No.: US 2022/0397823 A1
(43) Pub. Date: Dec. 15, 2022

(54) ORGANICALLY MODIFIED METAL OXIDE NANOPARTICLE, METHOD FOR PRODUCING SAME, EUV PHOTORESIST MATERIAL, AND METHOD FOR PRODUCING ETCHING MASK

(71) Applicant: NATIONAL INSTITUTE OF ADVANCED INDUSTRIAL SCIENCE AND TECHNOLOGY, Tokyo (JP)

(72) Inventors: Kiwamu SUE, Tsukuba-shi, Ibaraki (JP); Sho KATAOKA, Tsukuba-shi, Ibaraki (JP)

(21) Appl. No.: 17/785,147

(22) PCT Filed: Oct. 27, 2020
(86) PCT No.: PCT/JP2020/040226

§ 371 Date: Jun. 14, 2022

(30) Foreign Application Priority Data
Dec. 24, 2019 (JP) 2019-233067

(51) Int. Cl. G03F 7/004; C01G 25/02; C07F 7/00

(52) U.S. Cl. CPC G03F 7/0042; C01G 25/02; C07F 7/00; G03F 7/2004

(57) ABSTRACT

An organically modified metal oxide nanoparticle includes a core, a first modification group, and a second modification group. The core includes a plurality of metal atoms and a plurality of oxygen atoms bonded to the plurality of metal atoms. The first modification group is a saturated carboxylic acid/carboxylate ligand coordinated to the core. The second modification group is coordinated to the core, and is an inorganic anion having a smaller size than the first modification group and/or a saturated carboxylic acid/carboxylate ligand having a smaller molecular weight than the first modification group.

### TECHNICAL FIELD

The present invention relates to an organically modified metal oxide nanoparticle that can be used in a photoresist material employed in a process for producing a semiconductor, and the like, a method for producing the same, an EUV photoresist material, and a method for producing an etching mask.

Priority is claimed on Japanese Patent Application No. 2019-233067 filed Dec. 24, 2019, the content of which is incorporated herein by reference.

### BACKGROUND ART

In recent years, circuit patterns of semiconductors have been thinned, and research and development of lithography using extreme ultraviolet light (EUV light) has been accelerated. Along with the thinning of patterns, the thickness of a resist film used for pattern formation has been reduced. Therefore, there is a demand for a resist material having resistance to etching. A composite material with an inorganic substance such as a metal oxide and an organic substance has been studied as such a resist material having etching resistance.

A method has been proposed in which a nanoparticle of an oxide of a metal such as zirconium and hafnium, which is organically modified with an unsaturated carboxylic acid such as a methacrylic acid, is used in a negative tone resist material (Patent Documents 1 and 2). Since a nanoparticle of the metal oxide has the metal oxide in the core, a resist material including the nanoparticle of the metal oxide has features such as higher resistance during etching, as compared with a resist material of an organic substance, and further has a high sensitivity to EUV light due to a higher reactivity of a methacrylic acid. In addition, since the structure of the nanoparticle of the metal oxide has high symmetry, there is a low possibility that the nanoparticle of the metal oxide remains as insoluble matter on a wafer in a case where a resist material including the nanoparticle of the metal oxide is developed.

Moreover, a method has also been proposed in which a complex (a monomer or a salt) of a metal such as zirconium and hafnium and an organic substance typified by a carboxylic acid such as a methacrylic acid in a resist material is used (Patent Documents 3 to 5). Since the size of the complex of the organic substance itself is small, the resist material is suitable for thinning, as compared with a resist material including a nanoparticle core. However, this resist material has an increased proportion of the organic substance in a film thus formed, as compared with the resist material having a nanoparticle as the core. Therefore, this resist material has low resistance to etching. Furthermore, since the structure of the complex of the organic substance has low symmetry, there is a high possibility that the complex of the organic substance remains as insoluble matter on a wafer in a case where a resist material including the complex of the organic substance is developed.

### CITATION LIST

### Patent Documents

[Patent Document 1]
Japanese Unexamined Patent Application, First Publication No. 2017-173537
[Patent Document 2]
Japanese Unexamined Patent Application, First Publication No. 2015-157807
[Patent Document 3]
Japanese Unexamined Patent Application, First Publication No. 2015-108781
[Patent Document 4]
Japanese Unexamined Patent Application, First Publication No. 2012-185484
[Patent Document 5]
Japanese Unexamined Patent Application, First Publication No. 2001-72716

### SUMMARY OF INVENTION

### Technical Problem

In view of the above, the synthesis of an organically modified metal oxide nanoparticle with a core diameter controlled to be as small as possible is important for the development of a resist material to form a fine line pattern. Usually, an organically modified metal oxide nanoparticle with a small core diameter is produced by mixing an alkoxide of a metal such as zirconium with an organic substance such as a methacrylic acid in a non-aqueous solvent in an extremely low-humidity environment. However, the alkoxide is expensive, and further, expensive equipment such as a glove box needs to be installed and maintained in order to achieve an extremely low-humidity environment. Therefore, the organically modified metal oxide nanoparticle with a small core diameter has a problem in terms of production cost.

Furthermore, with regard to a reaction mechanism of a resist material during EUV exposure, it is known that decarboxylation proceeds in a case of using a carboxylic acid, but the detailed mechanism or important factors in the exposure operation are not necessarily clarified and there is a need to establish a method for controlling a resolution and a sensitivity with a resist material. With regard to the sensitivity, the sensitivity can be increased by using a reaction between the material itself and an additive to a resist liquid, or the like, or by selecting an appropriate solvent for a developer. On the other hand, the resolution greatly depends on the size or structure of the material itself.

In addition, a heating-and-drying operation is required to remove the solvent included in the resist liquid after film formation. Since an unsaturated carboxylic acid such as a methacrylic acid is easily polymerized, it cannot be said that the unsaturated carboxylic acid is necessarily suitable due to a reduction in the stability after film formation in consideration of the entire process, although the sensitivity is high. In a case where only one kind of unsaturated carboxylic acid is used as a ligand, volume shrinkage and local particle aggregation easily occur due to decarboxylation, polymerization, or the like. Therefore, variations in line widths occur, resulting in a decrease in a resolution. In a case where the resolution and the sensitivity can be adjusted while maintaining the solubility of the nanoparticles in the resist liquid by controlling the structure of the material itself, more specifically, by modifying with a plurality of ligands including a carboxylic acid having no unsaturated bond and controlling the composition thereof, it is possible to examine a more diversified method for adjusting the resist material.

The present invention has been made in view of such circumstances, and an object thereof is to provide an organically modified metal oxide nanoparticle which can be produced by a simple method and can increase the sensitivity and the resolution of a resist material, a method for producing the same, an EUV photoresist material, and a method for producing an etching mask.

### Solution to Problem

In a case where a resist material is irradiated with EUV, the reactivity, that is, the sensitivity of an organically modified metal oxide nanoparticle composed of a metal oxide and a ligand such as a carboxylic acid included in the resist material, and the resolution of a resist pattern thus formed greatly vary depending on the type, the constituent element and size, and the molecular weight of ligands such as a carboxylic acid to be coordinated with a constituent element of the nanoparticle core. The present inventors have found that the resolution of a resist film is improved since by coordinating at least two kinds of modification groups, that is, a saturated carboxylic acid having a high affinity (solubility) for a resist liquid or a solvent for a developer as a first modification group and a ligand (for example, an inorganic anion) having a smaller size (molecular weight) than the first modification group as a second modification group to a metal oxide core part to form a film filled with individual organically modified metal oxide nanoparticles more densely during film formation while avoiding the polymerization of the ligands during heating-and-drying, it is possible to suppress variations caused by volume shrinkage and particle aggregation upon irradiation with EUV light, that is, structural distribution in the film.

In addition, the reactivity of the organically modified metal oxide nanoparticle upon irradiation with EUV light greatly depends on the structure and the type of the ligand. The present inventors have found that in a case where two or more kinds of modification groups are used, a high solubility of a nanoparticle in a resist liquid or a high solubility of the nanoparticle in a solvent for a developer in a part not irradiated with EUV after irradiation with EUV light, which is required for the first modification group, is maintained, a low solubility of the nanoparticle in a solvent for a developer in a part irradiated with EUV after irradiation with EUV light is maintained while maintaining the interparticle distance closer to the second modification group, and the composition of these ligands is appropriately controlled, and it is possible to express a high sensitivity of a resist film to EUV light, in other words, a low solubility of the part irradiated with EUV in the developer after irradiation with EUV light.

The organically modified metal oxide nanoparticle of the present invention has a core including a plurality of metal atoms and a plurality of oxygen atoms bonded to the plurality of metal atoms; a first modification group which is a saturated carboxylic acid/carboxylate ligand coordinated to the core; and a second modification group which is coordinated to the core, and is an inorganic anion having a smaller size than the first modification group and/or a saturated carboxylic acid/carboxylate ligand having a smaller molecular weight than the first modification group. The EUV photoresist material of the present invention contains the organically modified metal oxide nanoparticle of the present invention and a solvent.

The method for producing an organically modified metal oxide nanoparticle of the present invention has a reacting step of reacting a metal oxynitrate and/or a metal oxyacetate with a saturated carboxylic acid in a hydrophilic liquid. The method for producing an etching mask of the present invention includes a film-forming step of applying the EUV photoresist material of the present invention onto a layer to be etched, followed by drying, to obtain a resist film, an exposing step of irradiating the resist film with EUV in a predetermined pattern, and a developing step of removing a portion not irradiated with EUV in the exposing step to form an etching opening.

### Advantageous Effects of Invention

According to the organically modified metal oxide nanoparticle, the method for producing an organically modified metal oxide nanoparticle, and the EUV photoresist material of the present invention, a resist material that can be produced by a simple method and has a high resolution and a high sensitivity can be obtained. In addition, according to the method for producing an etching mask of the present invention, a mask can be thinned.

### BRIEF DESCRIPTION OF DRAWINGS

FIG. 1 is an SEM image of a silicon wafer obtained in Example 1.

FIG. 2 is an SEM image of a silicon wafer obtained in Comparative Example 1.

FIG. 3 is a schematic diagram showing a change in the state of organically modified metal oxide nanoparticles during film formation, heating-and-drying, and EUV exposure of Example 1.

FIG. 4 is a schematic diagram showing a change in the state of organically modified metal oxide nanoparticles during film formation, heating-and-drying, and EUV exposure of Comparative Example 1.

### DESCRIPTION OF EMBODIMENTS

Hereinafter, embodiments of the present invention will be described in detail with reference to the drawings as appropriate. The drawings used in the following description may be enlarged for convenience in order to make the features of the present embodiments easy to understand, and dimensional ratios of the respective components may differ from the actual ones.

The organically modified metal oxide nanoparticle according to the embodiment of the present invention includes a core, a first modification group, and a second modification group. The core has a plurality of metal atoms and a plurality of oxygen atoms bonded to the plurality of metal atoms. The core includes metal oxides. In addition to metal oxide crystals, the core can include clusters having structures in which a plurality of metal atoms are crosslinked with a plurality of oxygen atoms. In addition, the core is preferably composed of the clusters. Metal oxide crystals and metal oxide clusters are common in that they are a combination of metal atoms and oxygen atoms, but in metal oxide crystals, individual particles themselves form a crystal structure in which metal atoms and oxygen atoms are arranged in a three-dimensionally regular manner, and have constant size (for example, 3 nm to 4 nm), whereas they are different in that the metal oxide cluster is a molecule in which each particle has a metal complex structure and the individual particles themselves do not have a crystal structure. The plurality of metal atoms may be composed of the same kind or different kinds thereof. The first modification group is a saturated carboxylic acid/carboxylate ligand coordinated to the core. The second modification group is coordinated to the core, and is an inorganic anion having a smaller size than the first modification group and/or a saturated carboxylic acid/carboxylate ligand having a smaller molecular weight than the first modification group.

The first modification group is preferably a saturated carboxylic acid/carboxylate ligand having 3 or more carbon atoms, and more preferably an isobutyric acid/carboxylate ligand from the viewpoint that the organically modified metal oxide nanoparticle is easily soluble in propylene glycol 1-monomethyl ether 2-acetate (PGMEA) which is a general-purpose solvent for a resist liquid, and the reactivity of the organically modified metal oxide nanoparticle upon irradiation with EUV light is improved. Furthermore, the metal is preferably one or more selected from the group consisting of zirconium (Zr), hafnium (Hf), and titanium (Ti), and more preferably Zr. The second modification group is preferably a nitrate ion and/or an acetic acid/carboxylate ligand.

The first modification group is not limited to the isobutyric acid/carboxylate ligand, but may also be another saturated carboxylic acid/carboxylate ligand such as a butyric acid/carboxylate ligand, a valeric acid/carboxylate ligand, and a caproic acid/carboxylate ligand.

In addition, in a case where the second modification group is the inorganic anion having a smaller size than the first modification group, the second modification group is not limited to the nitrate ion but may also be another inorganic anion such as a chloride ion and a hydroxide ion. In a case where the second modification group is the saturated carboxylic acid/carboxylate ligand having a smaller molecular weight than the first modification group, the second modification group is not limited to the acetic acid/carboxylate ligand, but may also be another saturated carboxylic acid/carboxylate ligand such as a formic acid/carboxylate ligand and a propionic acid/carboxylate ligand.

It is preferable that the organically modified metal oxide nanoparticle of the present embodiment be represented by General Formula M₆O₄(OH)₄XₙY₁₂₋ₙ, and have a structure in which a metal atom is crosslinked with the oxygen atom in the core. Here, M is the metal atom and is one or more selected from the group consisting of Zr, Hf, and Ti, X is the first modification group, Y is the second modification group, and 1≤n≤11 is satisfied. In addition, Z defined by X/(X+Y)×100, which represents a proportion of X and Y, preferably satisfies a relationship of 5% by mole≤Z≤95% by mole.

The size of the isobutyric acid/carboxylate ligand which is an example of the first modification group is about 0.53 nm, and the size of the nitrate ion which is an example of the second modification group is about 0.33 nm. The size of each of the first modification group and the second modification group can be determined from a distance between the atoms at both ends by preparing the molecule with, for example, 3D molecular model drawing software. By comparing the values, it can be confirmed that the size of the inorganic anion which is the second modification group is smaller than the size of the carboxylic acid/carboxylate ligand which is the first modification group.

The EUV photoresist material according to an embodiment of the present invention contains the organically modified metal oxide nanoparticle of the present embodiment and a solvent. Examples of the solvent include butyl acetate, PGMEA, methanol, ethanol, and propanol. The EUV photoresist material of the present embodiment may further contain a dispersant such as a carboxylic acid, a stabilizer, a photoresponsive agent such as a photoacid generator, and the like.

The method for producing an organically modified metal oxide nanoparticle according to an embodiment of the present invention has a reacting step of reacting a metal oxynitrate and/or a metal oxyacetate with a saturated carboxylic acid in a hydrophilic liquid. The saturated carboxylic acid is preferably isobutyric acid. It should be noted that another saturated carboxylic acid such as butyric acid, valeric acid, and caproic acid may also be used. Examples of the hydrophilic liquid include water, methanol, ethanol, propanol, and acetone. The reacting step can be carried out in an air atmosphere. Therefore, no equipment is required to realize an extremely low-humidity environment.

An example of the method for producing an organically modified metal oxide nanoparticle using a metal oxynitrate will be described. Isobutyric acid is added to an aqueous metal oxynitrate solution, the mixture is stirred, as necessary, and a nanoparticle thus produced is separated, recovered, and dried. In this manner, the organically modified metal oxide nanoparticle of the present embodiment can be obtained by a simple method. In a case where X is an isobutyric acid/carboxylate and Y is a nitrate ion, the organically modified metal oxide nanoparticle preferably satisfies a relationship of 50% by mole≤Z≤90% by mole. In addition, it is preferable that the metal oxynitrate be zirconium oxynitrate.

In addition, an example of the method for producing an organically modified metal oxide nanoparticle using a metal oxyacetate will be described. Isobutyric acid is added to an aqueous metal oxyacetate solution, the mixture is stirred as necessary, and the obtained precipitate is recovered by separation and dried. In this manner, the organically modified metal oxide nanoparticle of the present embodiment can be obtained by a simple method. In a case where X is isobutyric acid/carboxylate and Y is acetic acid/carboxylate, the organically modified metal oxide nanoparticle preferably satisfies a relationship of 50% by mole≤Z≤90% by mole. In addition, the metal oxyacetate is preferably zirconium oxyacetate.

The method for producing an etching mask according to an embodiment of the present invention includes a film-forming step, an exposing step, and a developing step. In the film-forming step, the EUV photoresist material of the present embodiment is applied onto a layer to be etched and dried to obtain a resist film. The type of the layer to be etched is not particularly limited. Examples of the layer to be etched include a silicon layer, a silicon oxide layer, and a silicon nitride layer.

In the exposing step, the resist film is irradiated with EUV light in a predetermined pattern. In the developing step, a portion not irradiated with EUV light in the exposing step is removed to form an etching opening. In the developing step, for example, a resist film is immersed in a developer such as butyl acetate, and a portion not irradiated with EUV light is dissolved in the developer and removed. By using the EUV photoresist material of the present embodiment, the line width of the etching mask can be reduced to, for example, 20 nm or less. Therefore, the mask can be made thinner and the layer to be etched can be finely etched.

### EXAMPLES

### Example 1

An aqueous zirconium oxynitrate solution was prepared by dissolving 1.2 g of zirconium oxynitrate in 3 mL of a 5 M aqueous nitric acid solution. 1 mL of isobutyric acid was added to 2 mL of this zirconium oxynitrate aqueous solution, and the mixture was stirred for 5 minutes and then allowed to stand at room temperature for 5 days. The obtained product was recovered by separation and vacuum-dried at room temperature for one day to obtain a white powder. As a result of elemental analysis (manufactured by PerkinElmer Co., Ltd., device name “Fully Automatic Elemental Analyzer 240011”) of the white powder, the carbon content was found to be 23.0% by weight, the nitrogen content was found to be 3.3% by weight, and a ratio of amounts of substances (so-called molar ratio) was found to be isobutyric acid:nitric acid=66:34≈7.9:4.1. As a result of thermogravimetric analysis (manufactured by Rigaku Corporation, device name “Thermo plus EVO2”) of the white powder, the weight loss rate was found to be 52%. Furthermore, as a result of IR analysis (manufactured by JASCO Corporation, device name “Fourier Transform Infrared Spectrophotometer FT/IR-4600”) of the white powder, absorption peaks derived from the carboxy group of isobutyric acid (1,530 cm⁻¹ and 1,430 cm⁻¹) could be confirmed.

0.3 g of the white powder was dissolved in 5.0 g of PGMEA. The undissolved white powder was removed using centrifugation and a filter with a pore size of 0.2 μm. As a result of dynamic light scattering analysis (manufactured by Malvern Panalytical Ltd., device name “Zetasizer Nano S”) of the solution after the removal (solution A for EUV exposure), the volume-based average particle diameter of the white powder was found to be about 2 nm. From this result, it was confirmed that the obtained white powder was an organically modified metal oxide nanoparticle in which isobutyric acid and nitric acid were coordinated with respect to the core composed of zirconium and oxygen.

Since the value of the particle diameter of about 2 nm obtained from the results of the dynamic light scattering analysis is a diameter of the dispersion including the surrounding ligands, it could be confirmed that the core is not a metal oxide crystal, but a cluster having zirconium crosslinked with oxygen. In addition, from the results of the thermogravimetric analysis, a proportion of the residues (ZrO₂) after the analysis was 48%. From the results of the IR analysis, the dynamic light scattering analysis, the elemental analysis, and the thermogravimetric analysis, it was confirmed that the white powder was a cluster Zr₆O₄(OH)₄(C₄H₇O₂)_{7.9}(NO₃)_{4.1} which has a ZrO₂-equivalent content of 46%, and has a structure in which zirconium was crosslinked with oxygen.

This solution A for EUV exposure was added dropwise onto a silicon wafer and rotated at 1,500 rpm for 60 seconds to form a film, and the film was then heated at 80° C. for 60 seconds to obtain a resist film A. A film thickness of the resist film A was measured with a spectroscopic ellipsometer (manufactured by Horiba Jobin Yvon Inc., device name “UVISEL”), and found to be about 20 nm. The resist film A was subjected to EUV exposure with an irradiation amount of 12 mJ/cm² to 76 mJ/cm² through a predetermined pattern (manufactured by Canon Inc., device name “High NA Micro-Region EUV Exposure Device”), and then immersed in butyl acetate for 30 seconds to perform development, whereby a part not irradiated with EUV in the resist film A was removed.

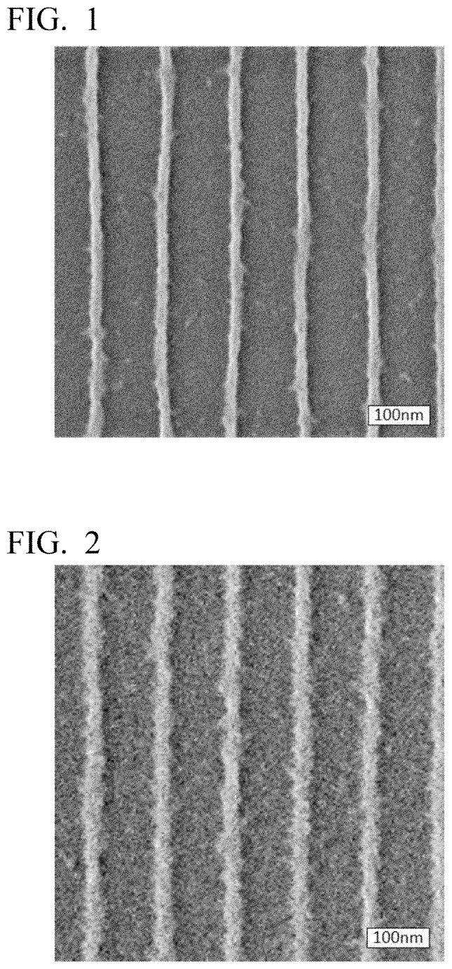

The silicon wafer after the development was observed by SEM. An SEM image of the silicon wafer after development in a case where EUV exposure was performed at an irradiation amount of 70 mJ/cm² is shown in FIG. 1. As shown in FIG. 1, it could be confirmed that the line width of the insolubilized resist film A (light-colored part) which is an etching mask remaining on the silicon wafer (dark-colored part) was 19 nm, the resist film A had a narrow line width and a small variation in the line widths, as compared with Comparative Example 1 which will be described later, and a nano-pattern with a high resolution was formed.

### Comparative Example 1

In a glove box, 1.02 g of a methacrylic acid was added to 1.40 g of an 85% zirconium butoxide 1-butanol solution, and the mixture was stirred and allowed to stand for about 3 weeks to obtain a single crystal of Zr₆O₄(OH)₄(MAA)₁₂. This single crystal was recovered by filtration under reduced pressure, vacuum-dried at room temperature for one day, and pulverized to obtain white powder. As a result of elemental analysis of the white powder, the carbon content was 36% by weight. As a result of thermogravimetric analysis of the white powder, the weight loss rate was 57%.

In addition, as a result of IR analysis of the white powder (manufactured by Thermo Fisher Scientific Inc., device name “NICOLET 6700”), an absorption peak (1,558 cm⁻¹) derived from the carboxy group of the methacrylic acid, an absorption peak (1,647 cm⁻¹) of an expansion/contraction vibration band of C═C, and an absorption peak (827 cm⁻¹) of an out-of-plane bending vibration band of a vinyl group CH could be confirmed. Furthermore, as a result of matrix-assisted laser desorption/ionization time-of-flight mass spectrometry (MALDI-TOF/MS) (manufactured by Bruker, device name “autoflex speed”) of the white powder, m/z 1702 was present and had almost the same molecular weight as a zirconia hexamer having a methacrylic acid coordinated. From the above, it could be confirmed that the obtained white powder was Zr₆O₄(OH)₄(MAA)₁₂.

0.09 g of the white powder was dissolved in 3.0 g of PGMEA. The undissolved white powder was removed using centrifugation and a filter with a pore size of 0.45 μm. As a result of dynamic light scattering analysis of the solution after this removal, the volume-based average particle diameter of the white powder was about 2 nm. From this result, it was confirmed that the obtained white powder was an organically modified metal oxide nanoparticle in which the methacrylic acid was coordinated with respect to the core composed of zirconium and oxygen. PGMEA was further added to this solution and diluted twice to obtain a solution B for EUV exposure. The solution B for EUV exposure was added dropwise onto a silicon wafer and rotated at 1,500 rpm for 60 seconds to form a film, and the film was then heated at 80° C. for 60 seconds to obtain a resist film B. In a case where the film thickness of the resist film B was measured with a spectroscopic ellipsometer, it was about 20 nm.

The resist film B was subjected to EUV exposure with an irradiation amount of 28 mJ/cm² to 60 mJ/cm² through a predetermined pattern, and then immersed in butyl acetate for 30 seconds for development, whereby a part not irradiated with EUV in the resist film B was removed.

The silicon wafer after the development was observed by SEM. An SEM image of the silicon wafer after development in a case where EUV exposure was performed at an irradiation amount of 46 mJ/cm² is shown in FIG. 2. As shown in FIG. 2, the line width of the insolubilized resist film B (light-colored part) which is an etching mask remaining on the silicon wafer (dark-colored part) was 21 nm, and a large variation was observed in the line width.

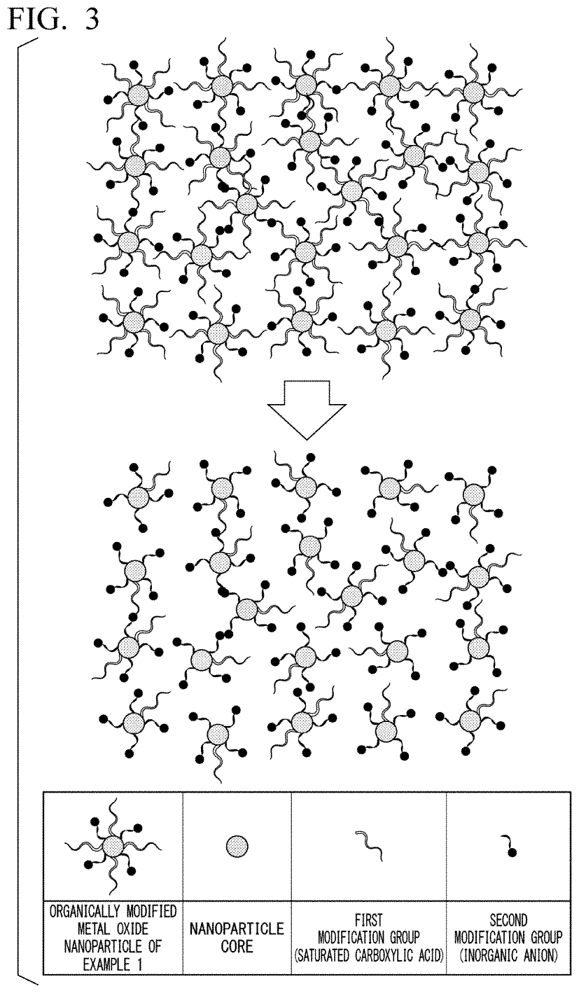

A schematic diagram showing a change in the state of organically modified metal oxide nanoparticles during film formation, heating-and-drying, and EUV exposure of Example 1 is shown in FIG. 3. In Example 1, an organically modified metal oxide nanoparticle in which isobutyric acid as a first modification group and nitric acid as a second modification group were coordinated with respect to a core composed of zirconium and oxygen was obtained. Since isobutyric acid which is a saturated carboxylic acid and nitric acid which is an inorganic anion are coordinated to the core in the nanoparticle having the present configuration, the organically modified metal oxide nanoparticles are densely and almost uniformly filled upon formation of the resist film A. For this reason, it is presumed that there is a low possibility that polymerization of the ligand occurs during heating-and-drying for removing the solvent included in the resist liquid after film formation, and during subsequent EUV exposure, there is less disturbance of the particle-filled structure in the film due to particle aggregation and the like in a case where the ligand is decomposed. Therefore, it is considered that a nano-pattern with a high resolution was formed.

Moreover, isobutyric acid which is the first modification group contributes to a high solubility in the resist liquid of the organically modified metal oxide nanoparticles in the solution A for EUV exposure and a high solubility in butyl acetate in a part not irradiated with EUV after EUV exposure. In addition, it is presumed that nitric acid which is the second modification group contributes to maintenance of the dense particle-filled structure of the nanoparticles by keeping the interparticle distance of the adjacent organically modified metal oxide nanoparticles small, and further, to low solubility of a part irradiated with EUV in butyl acetate EUV after EUV exposure. In Example 1, it is considered that an appropriate composition (Z=65.8% by mole) of isobutyric acid and nitric acid which are two kinds of ligands exhibited high sensitivity equal to or higher than that in Comparative Example 1.

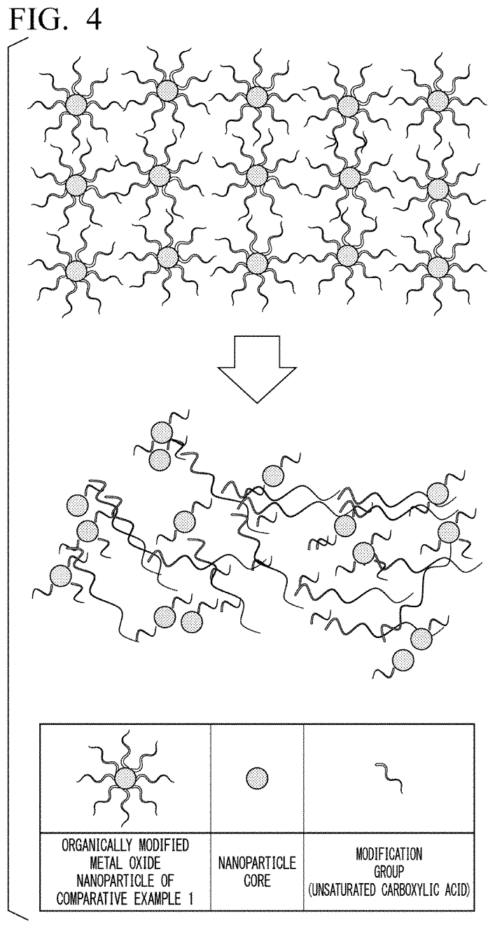

A schematic diagram showing a change in the state of organically modified metal oxide nanoparticles during film formation, heating-and-drying, and EUV exposure of Comparative Example 1 is shown in FIG. 4. In Comparative Example 1, it is considered that an organically modified metal oxide nanoparticle in which the methacrylic acid was coordinated with respect to the core composed of zirconium and oxygen was obtained. Since only the methacrylic acid which is an unsaturated carboxylic acid is coordinated to the core in the nanoparticle having the present configuration, the organically modified metal oxide nanoparticles are sparsely filled upon formation of the resist film B, as compared with Example 1. Therefore, it is presumed that volume shrinkage and particle aggregation proceeded due to the polymerization of methacrylic acid during heating-and-drying after film formation, and the decomposition during EUV exposure, resulting in variations in the particle-filled structure in the film. As a result, it is considered that a nano-pattern with a low resolution was formed.

1. An organically modified metal oxide nanoparticle, comprising:
a core including a plurality of metal atoms and a plurality of oxygen atoms bonded to the plurality of metal atoms;
a first modification group which is a saturated carboxylic acid/carboxylate ligand coordinated to the core; and
a second modification group which is coordinated to the core and is an inorganic anion having a smaller size than the first modification group and/or a saturated carboxylic acid/carboxylate ligand having a smaller molecular weight than the first modification group.

2. The organically modified metal oxide nanoparticle according to claim 1, wherein the first modification group is a saturated carboxylic acid/carboxylate ligand having 3 or more carbon atoms, and the second modification group is a nitrate ion and/or an acetic acid/carboxylate ligand.

3. The organically modified metal oxide nanoparticle according to claim 1, wherein the organically modified metal oxide nanoparticle is represented by General Formula M₆O₄(OH)₄XₙY₁₂₋ₙ and has a structure in which a metal atom is crosslinked with the oxygen atom in the core, where M is the metal atom and is one or more selected from the group consisting of Zr, Hf, and Ti, X is the first modification group, Y is the second modification group, and 1≤n≤11 is satisfied.

4. The organically modified metal oxide nanoparticle according to claim 1, wherein the metal is Zr.

5. An EUV photoresist material, comprising: the organically modified metal oxide nanoparticle according to claim 1; and a solvent.

6. A method for producing an organically modified metal oxide nanoparticle, the method comprising a reacting step of reacting a metal oxynitrate and/or a metal oxyacetate with a saturated carboxylic acid in a hydrophilic liquid.

7. The method for producing an organically modified metal oxide nanoparticle according to claim 6, wherein the saturated carboxylic acid is isobutyric acid, and the reacting step reacts a metal oxynitrate and/or a metal oxyacetate with isobutyric acid in a hydrophilic liquid.

8. The method for producing an organically modified metal oxide nanoparticle according to claim 7, wherein the reacting step is carried out in an air atmosphere.

9. The method for producing an organically modified metal oxide nanoparticle according to claim 6, wherein the metal oxynitrate is zirconium oxynitrate and the metal oxyacetate is zirconium oxyacetate.

10. A method for producing an etching mask, comprising:
a film-forming step of applying the EUV photoresist material according to claim 5 onto a layer to be etched, followed by drying, to obtain a resist film;
an exposing step of irradiating the resist film with EUV light in a predetermined pattern; and
a developing step of removing a portion not irradiated with EUV light in the exposing step to form an etching opening.
